(19) United States
(12) Patent Application Publication
(10) Pub. No.: US 2025/0107393 A1
(43) Pub. Date: Mar. 27, 2025

(54) Display Panel and Manufacturing Method Therefor, and Display Device

(71) Applicant: BOE Technology Group Co., Ltd., Beijing (CN)

(72) Inventor: Yanliu SUN, Beijing (CN)

(21) Appl. No.: 18/291,933

(22) PCT Filed: Sep. 28, 2022
(86) PCT No.: PCT/CN2022/122279

§ 371 Date: Jan. 25, 2024

(51) Int. Cl. H10K 59/80; H10K 59/12; H10K 59/121; H10K 59/122

(52) U.S. Cl. CPC H10K 59/80515; H10K 59/1201; H10K 59/121; H10K 59/122

(57) ABSTRACT

A display panel, a manufacturing method therefor and a display device are provided. The display panel includes: a base substrate, including a light emitting region and a non-light emitting region; at least one light emitting unit which is located on the light emitting region and includes a first electrode part; a second electrode part which is located on the non-light emitting region, and is located on at least one side of the first electrode part and electrically connected with the first electrode part; a square resistance of the first electrode part is greater than a square resistance of the second electrode part.

### CROSS-REFERENCE TO RELATED APPLICATION

The present application is a U.S. National Phase Entry of International Application PCT/CN2022/122279 having an international filing date of Sep. 28, 2022, and entitled “Display Panel and Manufacturing Method Therefor, and Display Device”, the contents of which are hereby incorporated herein by reference in their entireties.

### TECHNICAL FIELD

The present disclosure relates to, but is not limited to the field of display technologies, in particular to a display panel and a method for manufacturing the display panel, and a display device.

### BACKGROUND

Pixel island light field 3D display can bring together light emitting units of a great many viewpoints to achieve ultra-high Pixels per inch (PPI), and a single color pixel island lens can be designed to solve dispersion problem and achieve advantages such as increased visual field of view, thus the pixel island light field 3D display has been widely concerned by the industry.

However, in a 3D display process of light emitting units of a great many viewpoints, a crosstalk problem between adjacent light emitting units is prone to occur, which is always been a major obstacle to improving the display effect. Although an improvement may be made by emitting light from a focal plane of a pixel island lens, an intrinsic crosstalk problem between light emitting units due to transverse conduction of carriers in organic electroluminescent devices still causes great interference and affects the 3D display effect.

### SUMMARY

The following is a summary of subject matter described herein in detail. The summary is not intended to limit the scope of protection of the claims.

In one aspect, an embodiment of the present disclosure provides a display panel and the display panel includes:
a base substrate, including a light emitting region and a non-light emitting region;
at least one light emitting unit located on the light emitting region, and each light emitting unit includes a first electrode part;
at least one second electrode part located on the non-light emitting region, each second electrode part is located on at least one side of a first electrode part and electrically connected with the first electrode part;
a square resistance of the first electrode part is greater than a square resistance of the second electrode part.

In an exemplary implementation, a thickness of the first electrode part is less than a thickness of the second electrode part.

In an exemplary implementation, a ratio of the thickness of the first electrode part to the thickness of the second electrode part is 1/5 to 1/10.

In an exemplary implementation, the first electrode part has a thickness value of 100 angstroms to 200 angstroms and the second electrode part has a thickness value of 500 angstroms to 1000 angstroms.

In an exemplary implementation, multiple light emitting units are arranged along a first direction of the base substrate to form a light emitting unit row, and the at least one second electrode part is located on one side or two sides in a second direction of all or part of the light emitting units in the light emitting unit row, and the first direction intersects with the second direction.

In an exemplary implementation, a part of the light emitting units in the light emitting unit row forms a first pixel island, and a part of the light emitting units in the light emitting unit row forms a second pixel island, the first pixel island and the second pixel island are disposed adjacent to each other, the first pixel island is configured to display a first picture, the second pixel island is configured to display a second picture, and the first picture and the second picture are spliced to form a continuous image.

In an exemplary implementation, the light emitting units in the first pixel island form a first sub-picture, and the light emitting units in the second pixel island form a second sub-picture, and the first sub-picture and the second sub-picture are alternately arranged to form the continuous image.

In an exemplary implementation, the at least one second electrode part is in a strip shape and the at least one second electrode part extends along the first direction.

In an exemplary implementation, all or part of the light emitting units in the light emitting unit row emit light of a same color.

In an exemplary implementation, the multiple light emitting units are arranged along the second direction of the base substrate to form a light emitting unit column and at least part of the at least one second electrode part is located between all or part of adjacent light emitting units in the light emitting unit column.

In an exemplary implementation, all or part of the light emitting units in the light emitting unit column emit light of different colors.

In the exemplary implementation, at least one third electrode part is further included, the at least one third electrode part is located on the non-light emitting region, the at least one third electrode part is located on one side or two sides in the first direction of all or part of the light emitting units in the light emitting unit row, each third electrode part is electrically connected with a first electrode part, and a square resistance of the third electrode part is greater than a square resistance of a second electrode part.

In an exemplary implementation, a thickness of the third electrode part is less than a thickness of the second electrode part.

In an exemplary implementation, the first electrode part and the second electrode part are integrally formed.

In an exemplary implementation, a first dielectric layer is further included, the first dielectric layer is located on the non-light emitting region, the first dielectric layer is provided on a side of the second electrode part away from the base substrate, and an orthographic projection of the first dielectric layer on the base substrate is not overlapped with an orthographic projection of the first electrode part on the base substrate.

In an exemplary implementation, a second dielectric layer is further included, the second dielectric layer is located on the light emitting region and the non-light emitting region, the second dielectric layer is provided on a side of the first dielectric layer away from the base substrate, and the second dielectric layer covers at least a part of the first electrode part and at least a part of the first dielectric layer.

In an exemplary implementation, a pixel definition layer is further included, at least part of the pixel definition layer is located on the non-light emitting region, and at least part of the second electrode part is provided on a side of the pixel definition layer away from the base substrate.

In an exemplary implementation, each light emitting unit further includes a second electrode and a light emitting layer, the second electrode and the light emitting layer are located on the light emitting region, the second electrode is located on a side of the first electrode part close to the base substrate, and the light emitting layer is located between the second electrode and the first electrode part.

In an exemplary implementation, a lens layer is further included, the lens layer is located on a side of the light emitting unit away from the base substrate, and an orthographic projection of the lens layer on the base substrate is overlapped with an orthographic projection of the light emitting unit on the base substrate.

In another aspect, the present disclosure further provides a display device, including the aforementioned display panel.

In yet another aspect, the present disclosure further provides a method for manufacturing a display panel, the display panel includes a base substrate, the base substrate includes a light emitting region and a non-light emitting region; the method for manufacturing the display panel includes:
forming a first electrode part on the light emitting region of the base substrate and forming a second electrode part on the non-light emitting region of the base substrate;
wherein the second electrode part is located on at least one side of the first electrode part;
the first electrode part is electrically connected with the second electrode part, and a square resistance of the first electrode part is greater than a square resistance of the second electrode part.

In an exemplary implementation, forming the first electrode part on the light emitting region of the base substrate and forming the second electrode part on the non-light emitting region of the base substrate includes:
forming a conductive material layer on the base substrate, wherein the conductive material layer covers the light emitting region and the non-light emitting region;
forming a first dielectric layer on the conductive material layer on the non-light emitting region; and
etching the conductive material layer on the light emitting region so that a thickness of the conductive material layer on the light emitting region is less than a thickness of the conductive material layer on the non-light emitting region; forming the first electrode part by the conductive material layer located on the light emitting region and forming the second electrode part by the conductive material layer located on the non-light emitting region.

Other aspects may become clear after the accompanying drawings and the detailed description are read and understood.

### BRIEF DESCRIPTION OF DRAWINGS

Accompanying drawings are used for providing an understanding for technical solutions of the present application and form a part of the specification, are used for explaining the technical solutions of the present application together with embodiments of the present application, and do not constitute a limitation on the technical solutions of the present application.

FIG. 1 is a first schematic diagram of a structure of a display panel according to an exemplary embodiment of the present disclosure.

FIG. 2 is a first cross-sectional view of a display panel according to an exemplary embodiment of the present disclosure.

FIG. 3 is a second cross-sectional view of a display panel according to an exemplary embodiment of the present disclosure.

FIG. 4 is a second schematic diagram of a structure of a display panel according to an exemplary embodiment of the present disclosure.

FIG. 5 is a schematic diagram of a structure of a light emitting unit in a display panel according to an exemplary embodiment of the present disclosure.

FIG. 6a is a schematic diagram of a display panel after a conductive material layer is formed according to an exemplary embodiment of the present disclosure.

FIG. 6b is a schematic diagram of a display panel after a first dielectric layer is formed according to an exemplary embodiment of the present disclosure.

FIG. 6c is a schematic diagram of a display panel after a first electrode part and a second electrode part are formed according to an exemplary embodiment of the present disclosure.

FIG. 7 is a schematic diagram of a curve of carriers after modeling and simulation of a display panel according to an exemplary embodiment of the present disclosure.

FIG. 8a is a first schematic diagram of a light emitting distribution of a display panel according to an exemplary embodiment of the present disclosure.

FIG. 8b is a second schematic diagram of a light emitting distribution of a display panel according to an exemplary embodiment of the present disclosure.

FIG. 9 is a schematic diagram of a light emitting morphology of a related display panel.

FIG. 10 is a schematic diagram of a picture displayed by a first pixel island and a second pixel island in a display panel according to an exemplary embodiment of the present disclosure.

FIG. 11 is a schematic diagram of a spliced picture displayed by a first pixel island and a second pixel island in a display panel according to an exemplary embodiment of the present disclosure.

FIG. 12 is a schematic diagram of a light emitting morphology of a display panel according to an exemplary embodiment of the present disclosure.

### DETAILED DESCRIPTION

To make objectives, technical solutions, and advantages of the present disclosure clearer, the embodiments of the present disclosure will be described in detail below in combination with the accompany drawings. It is to be noted that the implementations may be practiced in various forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to the shapes, numerical values, or the like shown in the drawings.

Ordinal numerals “first”, “second”, “third”, etc., in the specification are set not to form limitations on number but only to avoid the confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to the direction according to which each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, a connection may be fixed connection, or detachable connection, or integral connection. The connection may be mechanical connection or electrical connection. The connection may be direct connection, or indirect connection through an intermediate, or internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows through.

In the specification, a first electrode may be a drain electrode, and a second electrode may be a source electrode. Or, the first electrode may be a source electrode, and the second electrode may be a drain electrode. In cases that transistors with opposite polarities are used, or a current direction changes during working of a circuit, or the like, functions of the “source electrode” and the “drain electrode” may sometimes be exchanged. Therefore, the “source electrode” and the “drain electrode” may be exchanged in the specification.

In the specification, “electrical connection” includes connection of the composition elements through an element with a certain electrical action. The “element with the certain electrical action” is not particularly limited as long as electric signals between the connected composition elements may be sent and received. Examples of the “element with the certain electrical action” not only include electrodes and wirings, but also include switch elements such as transistors, resistors, inductors, capacitors, other elements with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

In the present disclosure, “about” refers to that a boundary is not defined so strictly and numerical values within process and measurement error ranges are allowed.

FIG. 9 is a schematic diagram of a light emitting morphology of sub-pixels in a related display panel. According to a research of the inventor of the present application, in a display panel with the pixel island light field 3D pixel arrangement structure currently adopted, there are conductive layers such as charge generation layers in sub-pixels, and these layers have relatively strong transverse carrier conduction capability, so that carriers participating in light emitting are shunted to peripheral regions, so that a light emitting area becomes larger, resulting in a non-rectangular light emitting morphology of sub-pixels, a certain crosstalk arc exists at an edge of the light emitting morphology of sub-pixels, and the light emitting area of sub-pixels also expands with voltage changes, as shown in FIG. 9. Crosstalk of sub-pixels will make adjacent sub-pixels unable to achieve accurate splicing, which will affect the display effect.

An exemplary embodiment of the present disclosure provides a display panel, including:
a base substrate, including a light emitting region and a non-light emitting region;
multiple light emitting units located on the light emitting region, wherein each light emitting unit includes a first electrode part;
a second electrode part located on the non-light emitting region, the second electrode part located on at least one side of the first electrode part and electrically connected with the first electrode part; and
a square resistance of the first electrode part is greater than a square resistance of the second electrode part.

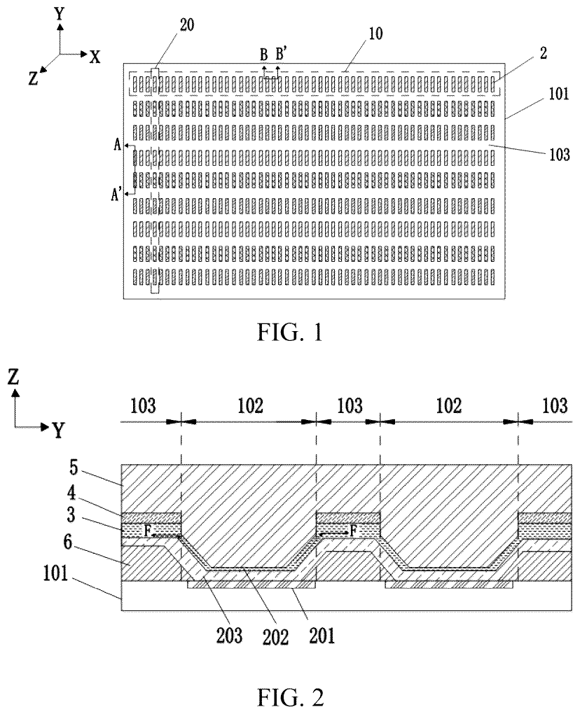

FIG. 1 is a first schematic diagram of a structure of a display panel according to an exemplary embodiment of the present disclosure. As shown in FIG. 1, in a direction parallel to a plane where the display panel is located, the display panel includes: a base substrate 101 and multiple light emitting units 2. The base substrate 101 includes a light emitting region and a non-light emitting region 103, the multiple light emitting units 2 are located on the light emitting region of the base substrate 101, and the multiple light emitting units 2 are arranged at intervals on the base substrate 101. The light emitting units 2 may emit light, for example red light, green light, blue light or white light for displaying an image. The non-light emitting region 103 does not display an image and may completely or partially surround the light emitting units 2.

In an exemplary implementation, as shown in FIG. 1, the multiple light emitting units 2 are arranged at intervals along a first direction (direction X) of the base substrate 101 to form a light emitting unit row 10 and the non-light emitting region 103 is provided between adjacent light emitting units 2 in the light emitting unit row 10. The multiple light emitting units 2 are arranged at intervals along a second direction (direction Y) of the base substrate 101 to form a light emitting unit column 20. The light emitting units 2 in the light emitting unit row 10 emit light of a same color. Adjacent light emitting units 2 in the light emitting unit column 20 emit light of different colors. Among them, the first direction intersects with the second direction, for example, the first direction is perpendicular to the second direction.

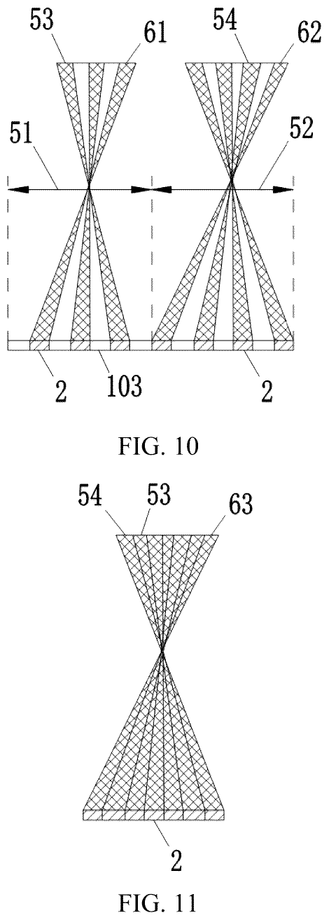

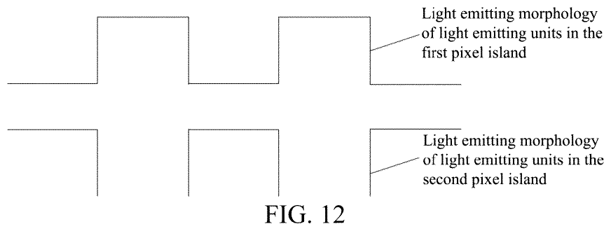

FIG. 10 is a schematic diagram of a picture displayed by a first pixel island and a second pixel island in a display panel according to an exemplary embodiment of the present disclosure. FIG. 11 is a schematic diagram of a continuous picture displayed by a first pixel island and a second pixel island in a display panel according to an exemplary embodiment of the present disclosure. In an exemplary implementation, as shown in FIG. 10 and FIG. 11, a part of adjacent light emitting units 2 in the light emitting unit row 10 may constitute a first pixel island 51, a part of adjacent light emitting units 2 may constitute a second pixel island 52, and the first pixel island 51 and the second pixel island 52 are provided adjacent to each other. The first pixel island 51 may display a first picture 61 and the second pixel island 52 may display a second picture 62. The first picture 61 and the second picture 62 may be overlapped and spliced with each other to form a continuous image 63.

Specifically, the first pixel island 51 may include three light emitting units 2 arranged at intervals along the first direction (direction X) of the base substrate 101, each of the light emitting units 2 in the first pixel island 51 forms a first sub-picture 53, and the first sub-picture 53 formed by each of the light emitting units 2 is arranged at intervals to form the first picture 61. The second pixel island 52 may include four light emitting units 2 arranged at intervals along the first direction (direction X) of the base substrate 101, each of the light emitting units 2 in the second pixel island 52 forms a second sub-picture 54, and the second sub-picture 54 formed by each of the light emitting units 2 is arranged at intervals to form the second picture 62. The first sub-picture 53 formed by each of the light emitting units 2 in the first pixel island 51 is located between adjacent second sub-pictures 54 and compensates the non-display region between the adjacent second sub-pictures 54 so that the first pictures 61 and the second pictures 62 can be overlapped and spliced with each other to form a continuous image 63, that is, first sub-pictures 53 and second sub-pictures 54 are alternately arranged along the first direction.

The above configuration of the display panel of the exemplary embodiment of the present disclosure can eliminate influence of the non-light emitting region 103 between the adjacent light emitting units 2 on pictures and avoid appearance of the non-display region on the pictures displayed by the display panel.

In an exemplary implementation, as shown in FIG. 1, the display panel may have a rectangular shape. In some embodiments, the display panel may also be a circular shape, an elliptical shape, or a polygonal shape such as a triangle and a pentagon.

In an exemplary implementation, the display panel may be a pad display panel. In some embodiments, the display panel may be other types of display panels as well. For example, a flexible display panel, a foldable display panel, a rollable display panel, and the like.

In an exemplary implementation, in a direction perpendicular to a plane where the display panel is located, the display panel includes a base substrate, a drive circuit provided on the base substrate, and a light emitting unit provided on the drive circuit. The drive circuit may include at least one thin film transistor (TFT), and each thin film transistor may include a gate, a gate insulating layer, a semiconductor layer, a source and a drain. The semiconductor layer of the thin film transistor may include silicon, such as amorphous silicon (a-Si), polycrystalline silicon (poly-Si) or low temperature polycrystalline silicon or may include an oxide, such as indium gallium zinc oxide (IGZO), but implementation of the present disclosure is not limited thereto.

The light emitting units in the display panel of this embodiment being organic light emitting diodes (OLED) will be described as an example hereinafter, but the display panel of this embodiment is not limited thereto. In another embodiment, the light emitting units in the display panel may be micro light emitting diodes (Micro-LED) or a quantum dot light emitting diode (QLED). For example, a light emitting layer of the light emitting units in the display panel may include an organic material, an inorganic material, quantum dots, an organic material and quantum dots, an inorganic material and quantum dots, or an organic material, an inorganic material and quantum dots.

FIG. 2 is a first cross-sectional view of a display panel according to an exemplary embodiment of the present disclosure. FIG. 2 may be a cross-sectional view taken along an A-A′ direction in FIG. 1. FIG. 2 illustrates a cross-sectional view of two light emitting units. In an exemplary implementation, the display panel according to the embodiment of the present disclosure may include more light emitting units (see FIG. 1).

In an exemplary implementation, as shown in FIG. 2, the base substrate 101 includes a light emitting region 102 and a non-light emitting region 103. Light emitting units are located on the light emitting region 102 of the base substrate 101 and an orthographic projection of the light emitting units on the base substrate 101 is not overlapped with an orthographic projection of the non-light emitting region 103 on the base substrate. Each light emitting unit includes a second electrode 201 and a first electrode part 202 which are disposed opposite to each other, and a light emitting functional layer 203 which is located between the second electrode 201 and the first electrode part 202. The second electrode 201 is located on a side of the first electrode part 202 close to the base substrate 101 and is electrically connected with the drive circuit. The light emitting functional layer 203 may include a hole injection layer, a hole transport layer, a light emitting layer, an electron transport layer and an electron injection layer. Among them, the first electrode part 202 may serve as a cathode of the light emitting unit and the second electrode 201 may serve as an anode of the light emitting unit.

In an exemplary implementation, as shown in FIG. 2, the display panel of the exemplary embodiment of the present disclosure further includes second electrode parts 3, the second electrode parts 3 are located on the non-light emitting region 103 of the base substrate 101, and an orthographic projection of the second electrode parts 3 on the base substrate 101 is not overlapped with the orthographic projection of the light emitting region 102 on the base substrate 101. Each second electrode part 3 is located on at least one side of a first electrode part 202 and is electrically connected with the first electrode part 202. A square resistance of the first electrode part 202 is greater than a square resistance of the second electrode part 3, so that a square resistance difference is formed between the first electrode part 202 and the second electrode part 3.

In an exemplary implementation, as shown in FIG. 1, the second electrode parts 3 are located on one side or two sides of in the second direction (direction Y) of all or part of the light emitting units 2 in the light emitting unit row 10, for example, the second electrode parts 3 are located on two sides of all of the light emitting units 2 in the light emitting unit row 10 in the second direction (direction Y). The first electrode parts 202 of all the light emitting units 2 in the light emitting unit row 10 are electrically connected with the second electrode parts 3, so that transverse carriers generated by the light emitting units 2 in the light emitting unit row 10 can be transmitted to the second electrode parts 3 along the second direction, thereby reducing a transmission extent of transverse carriers in the first direction, reducing the mutual-transmission of transverse carriers between adjacent light emitting units 2 in the light emitting unit row 10, and avoiding crosstalk, so that a light emitting morphology of the light emitting units 2 can be a regular shape, for example, a rectangle, as shown in FIG. 12. Thereby, pictures emit by adjacent pixel islands can be accurately spliced to form a continuous and uniform image.

In the display panel of the exemplary embodiment of the present disclosure, the square resistance of the first electrode part 202 is greater than the square resistance of the second electrode part 3, so that when a light emitting unit is electrified and emits light, the pressure difference between the second electrode part 3 and the second electrode 201 of the light emitting unit is formed, as a result, transverse carriers generated by the light emitting unit are transmitted in a direction towards the second electrode part 3 (direction F), a transmission extent of transverse carriers to adjacent light emitting units is reduced, crosstalk between adjacent light emitting units is reduced, and crosstalk between viewpoints in spliced light field 3D displaying of the display panel is further reduced, thus increasing a visible space. Since the second electrode part 3 is located on the non-light emitting region 103 of the base substrate 101, transverse carriers are transmitted to the second electrode part 3, and light emission for displaying of the light emitting unit is not affected.

In an exemplary implementation, as shown in FIG. 2, a thickness of the first electrode part 202 is less than a thickness of the second electrode part 3 so that the square resistance of the first electrode part 202 is greater than the square resistance of the second electrode part 3.

In some embodiments, a thickness of a first electrode part of the display panel of an exemplary embodiment of the present disclosure may be substantially the same as a thickness of a second electrode part, an area of an orthographic projection of the first electrode part on the base substrate is less than an area of an orthographic projection of the second electrode part on the base substrate, so that a square resistance of the first electrode part is greater than a square resistance of the second electrode part, which will not be repeated here the an exemplary embodiment of the present disclosure.

In an exemplary implementation, a ratio of the thickness of the first electrode part 202 to the thickness of the second electrode part 3 may be about 1/5 to 1/10. For example, the ratio of the thickness of the first electrode part 202 to the thickness of the second electrode part 3 may be about 1/6 to 1/8.

In an exemplary implementation, the first electrode part 202 may have a thickness value of about 100 angstroms to 200 angstroms, and for example, the first electrode part 202 may have a thickness value of about 130 angstroms to 180 angstroms. The second electrode part 3 may have a thickness value of about 500 angstroms to 1000 angstroms, and for example, the second electrode part 3 may have a thickness value of about 600 angstroms to 800 angstroms.

In an exemplary implementation, the first electrode part 202 has a small thickness and has a semi-transparent and semi-reflective characteristic and the first electrode part 202 can transmit part of the light and reflect part of the light to achieve the light emission for displaying of the light emitting unit.

In an exemplary implementation, the second electrode part 3 and the first electrode part 20 may be located in a same film layer 2 and formed integrally, that is, the second electrode part 3 may be made of a same material as the first electrode part 202.

In an exemplary implementation, materials of both the first electrode part 202 and the second electrode part 3 may be transparent or translucent materials with high work functions such as indium tin oxide (ITO), silver (Ag), nickel oxide (NiO), aluminum (Al), or graphene.

In an exemplary implementation, as shown in FIG. 2, the display panel of an exemplary embodiment of the present disclosure further includes a first dielectric layer 4. The first dielectric layer 4 is located on the non-light emitting region 103 of the base substrate 101. The first dielectric layer 4 is provided on a side of the second electrode part 3 away from the base substrate 101, and an orthographic projection of the first dielectric layer 4 on the base substrate is overlapped with an orthographic projection of the second electrode part 3 on the base substrate, and the orthographic projection of the first dielectric layer 4 on the base substrate is not overlapped with an orthographic projection of the first electrode part 202 on the base substrate 101. The first dielectric layer 4 has an encapsulation function. Among them, the first dielectric layer 4 may be made of an inorganic material, and for example, the first dielectric layer 4 may be made of tetrafluoroethylene (TFE).

In an exemplary implementation, as shown in FIG. 2, the display panel of an exemplary embodiment of the present disclosure further includes a second dielectric layer 5. The second dielectric layer 5 is located on the light emitting region 102 and the non-light emitting region 103 of the base substrate 101. The second dielectric layer 5 is provided on a side of the first dielectric layer 4 and the first electrode part 202 away from the base substrate 101, and the second dielectric layer 5 covers at least a part of the first electrode part 202 and at least a part of the first dielectric layer 4. The second dielectric layer 5 has an encapsulation function and can encapsulate the first electrode part 202 and the second electrode part 3. Among them, the second dielectric layer 5 may be made of an inorganic material, and for example, the second dielectric layer 5 may be made of tetrafluoroethylene (TFE).

In an exemplary implementation, as shown in FIG. 2, the display panel of an exemplary embodiment of the present disclosure further includes a pixel definition layer 6. At least a part of the pixel definition layer 6 is located on the non-light emitting region 103 of the base substrate 101, and at least a part of the second electrode part 3, the first dielectric layer 4 and a part of the light emitting functional layer 203 are provided on a side of the pixel definition layer 6 away from the base substrate 101. The pixel definition layer 6 is provided with an opening, the opening is located on the light emitting region 102 of the base substrate 10, and a part of the light emitting functional layer 203 of the light emitting unit and the first electrode part 202 are sequentially stacked in the opening. Among them, a vertical section of the opening is an inverted trapezoid, which is wider at the top and narrower at the bottom.

In an exemplary implementation, as shown in FIG. 1, the second electrode parts may be in a strip shape, the second electrode parts extend along the first direction and are located at one side or two sides of the light emitting unit row 10 in the second direction. The second electrode parts are electrically connected with the first electrode parts in part or all of the light emitting units in the light emitting unit row 10, so that transverse carriers generated by the light emitting units 2 in the light emitting unit row 10 are transmitted to the second electrode parts along the second direction.

In some embodiments, the second electrode parts may be in a block shape and multiple second electrode parts are arranged along the first direction to form a second electrode part row. The second electrode part rows are located on one side or two sides of a light emitting unit row. The second electrode parts in each second electrode part row are electrically connected with the first electrode parts of some or all of the light emitting units in adjacent light emitting unit row(s), so that transverse carriers generated by the light emitting units 2 in the light emitting unit row 10 are transmitted to the second electrode parts along the second direction.

In an exemplary implementation, as shown in FIG. 1, all or part of the light emitting units 2 in the light emitting unit row 10 emit light of a same color. For example, all the light emitting units 2 in the light emitting unit row 10 emit light of a same color. For example, all the light emitting units 2 in the light emitting unit row 10 emit red light, green light, or blue light.

In an exemplary implementation, as shown in FIG. 1, at least part of the second electrode parts are located between all or part of adjacent light emitting units 2 in the light emitting unit column 20, so that transverse carriers generated by the light emitting units 2 are transmitted to the second electrode parts along the second direction.

In an implementation, as shown in FIG. 1, all or part of the light emitting units 2 in the light emitting unit column 20 emit light of different colors. For example, adjacent light emitting units 2 in the light emitting unit column 20 emit light of different colors. For example, the light emitting unit column 20 includes a first light emitting unit, a second light emitting unit and a third light emitting unit that are sequentially arranged along the second direction, wherein the first light emitting unit emits red light, the second light emitting unit emits green light, and the third light emitting unit emits blue light.

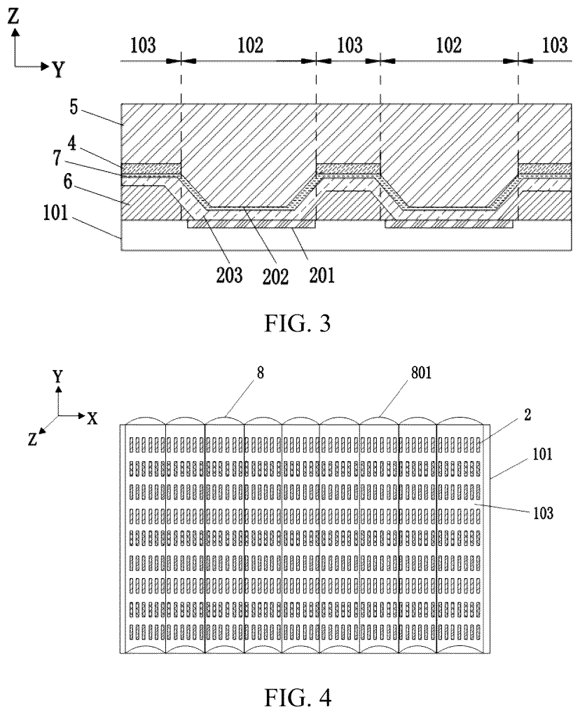

FIG. 3 is a second cross-sectional view of a display panel according to an embodiment of the present disclosure. FIG. 3 may be a cross-sectional view taken along a B-B′ direction in FIG. 1. FIG. 3 illustrates a cross-sectional view of two light emitting units. In an exemplary implementation, the display panel according to an embodiment of the present disclosure may include more light emitting units (see FIG. 1).

In an exemplary implementation, as shown in FIG. 1 and FIG. 3, a display panel of an exemplary embodiment of the present disclosure further includes third electrode parts 7. The third electrode parts 7 are located on the non-light emitting region 103 of the base substrate 101, and the third electrode parts 7 are located on one side or two sides of all or part of the light emitting units 2 in the light emitting unit row 10 in the first direction. The third electrode parts 7 are electrically connected with the first electrode parts 202 of the light emitting units 2 in the light emitting unit row 10, for example, each third electrode part 7 is located between adjacent light emitting units 2 in the light emitting unit row 10 and each third electrode part 7 is electrically connected with first electrode parts 202 of the adjacent light emitting units 2 in the light emitting unit row 10 respectively. A square resistance of a third electrode part 7 is greater than a square resistance of a second electrode part. Transverse carriers generated by the light emitting units 2 in the light emitting unit row 10 are transmitted to the second electrode parts 3 in the second direction, thereby reducing the transmission of the transverse carriers to the third electrode parts 7 along the first direction, as a result, mutual-transmission of transverse carriers of adjacent light emitting units 2 in the light emitting unit row 10 is reduced and crosstalk is avoided.

In an exemplary implementation, a thickness of the third electrode part 7 is less than a thickness of the second electrode part 3 and the thickness of the third electrode part 7 may be substantially the same as a thickness of the first electrode part 202, so that a square resistance of the third electrode part 7 is greater than a square resistance of the second electrode part 3.

In some embodiments, a thickness of the third electrode part of the display panel of an exemplary embodiment of the present disclosure may be substantially the same as a thickness of the second electrode part and an area of an orthographic projection of the third electrode part on the base substrate is less than an area of an orthographic projection of the second electrode part on the base substrate, so that the square resistance of the third electrode part is greater than the square resistance of the second electrode part, which will not be repeated here in an exemplary embodiment of the present disclosure.

In an exemplary implementation, the third electrode part 7 may be located in a same film layer as the first electrode part 202 and formed integrally, that is, the third electrode part 7 may be made of a same material as the first electrode part 202.

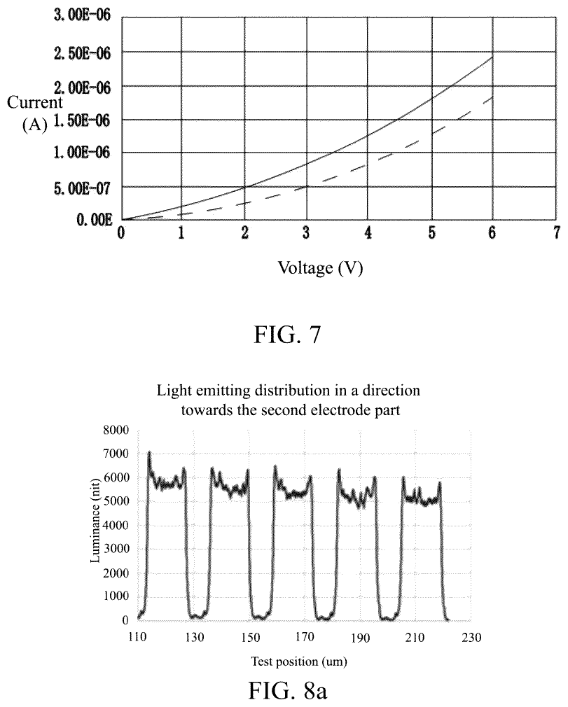

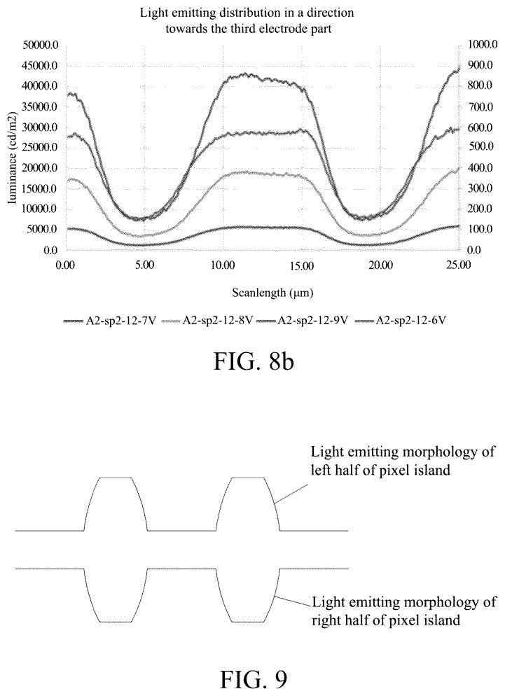

FIG. 7 is a schematic diagram of a curve of carriers after modeling and simulation of a display panel. Among them, a solid line in FIG. 7 is a curve of carriers when a thickness of a second electrode part is greater than each of a thickness of the first electrode part and a thickness of the third electrode part; a dotted line in FIG. 7 is a curve of carriers when the thickness of the first electrode part, the thickness of the second electrode part and the thickness of the third electrode part are substantially the same. As shown in FIG. 7, according to Technology Computer-Aided Design (TCAD) modeling and simulation of the display panel, it is found that when the thicknesses of the first electrode part, the thickness of the second electrode part and the thickness of the third electrode part are substantially the same, transverse conduction of carriers in all directions of the light emitting units is the same, and there is obvious crosstalk between adjacent light emitting units, which affects the display effect of the display panel. When the thickness of the second electrode part is greater than each of the thickness of the first electrode part and the thickness of the third electrode part, a quantity of carriers moving in a direction towards the second electrode part increases and a quantity of carriers moving in a direction towards the third electrode part decreases. Since the second electrode part is located in the non-light emitting region, no light is generated, and light emitting distribution of a light emitting unit in a direction towards the second electrode part is shown in FIG. 8a. Since the quantity of the carriers moving in the direction towards the third electrode part is reduced, crosstalk between the adjacent light emitting units is reduced, and light emitting distribution of the light emitting unit in the direction towards the third electrode part is shown in FIG. 8b. Therefore, the above structures of the first electrode part, the second electrode part and the third electrode part of the display panel of the exemplary embodiment of the present disclosure can reduce mutual-transmission of transverse carriers between adjacent light emitting units 2, and crosstalk is avoided, so that light emitting distribution of the display panel of the exemplary embodiment of the present disclosure is uniform.

FIG. 4 is a second schematic diagram of a structure of a display panel according to an exemplary embodiment of the present disclosure. In an exemplary implementation, as shown in FIG. 4, the display panel of the exemplary embodiment of the present disclosure further includes a lens layer 8. The lens layer 8 is located on a side of the light emitting units 2 away from the base substrate 101, and an orthographic projection of the lens layer 8 on the base substrate 101 is overlapped with an orthographic projection of at least one of the light emitting units 2 on the base substrate 101, and, for example, the lens layer 8 covers all the light emitting units 2 on the base substrate 101. The lens layer 8 includes multiple lens pillars 801, the multiple lens pillars extend along a second direction (direction Y), and an orthographic projection of the lens pillars 801 on the base substrate 101 covers an orthographic projection of at least one light emitting unit column on the base substrate 101. The lens pillars 801 in the lens layer 8 can converge light of each light emitting unit 2 in the light emitting unit column, change a propagation direction of the light, so that the light may form a continuous light emitting surface and avoid the light emitting surface from forming a non-light emitting region, thereby improving the display effect and implementing colorful 3D display.

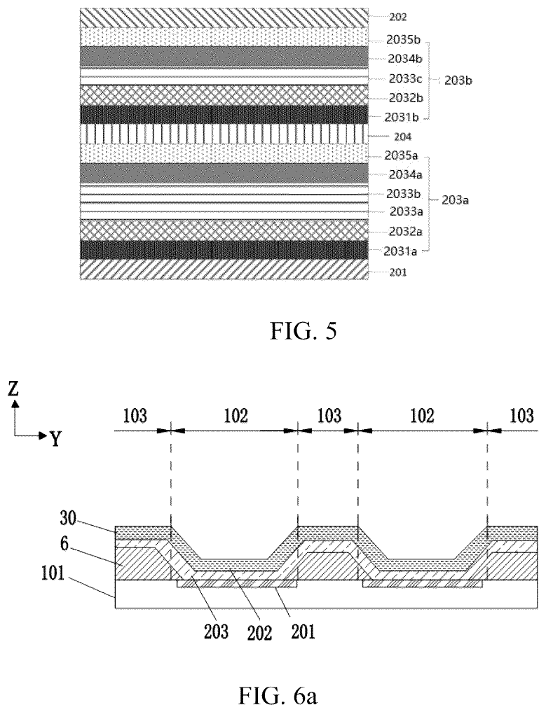

FIG. 5 is a schematic diagram of a structure of a light emitting unit in a display panel according to an exemplary embodiment of the present disclosure. In an exemplary implementation, as shown in FIG. 5, the light emitting unit 2 includes a second electrode 201 and a first electrode part 202 which are disposed opposite to each other, a first light emitting functional layer 203a and a second light emitting functional layer 203b located between the second electrode 201 and the first electrode part 202, and a charge generation layer 204 located between the first light emitting functional layer 203a and the second light emitting functional layer 203b. The first light emitting functional layer 203a is located on a side of the second light emitting functional layer 203b close to the second electrode 201 and the first light emitting functional layer 203a and the second light emitting functional layer 203b are connected in series with each other.

In an exemplary implementation, the first light emitting functional layer 203a and the second light emitting functional layer 203b may emit light under drive of an electric field between the second electrode 201 and the first electrode part 202 for displaying. The charge generation layer 204 has strong carrier conductivity, and can ensure that electrons and holes can be conducted in the first light emitting functional layer 203a and the second light emitting functional layer 203b, so that both the first light emitting functional layer 203a and the second light emitting functional layer 203b can emit light normally.

In an exemplary implementation, the first light emitting functional layer 203a may include a hole injection layer 2031a, a hole transport layer 2032a, a first organic emitting layer 2033a, a second organic emitting layer 2033b, an electron transport layer 2034a, and an electron injection layer 2034a provided sequentially along a direction away from the base substrate 101. The first organic emitting layer 2033a may emit red light and the second organic emitting layer 2033b may emit green light. In practical applications, since the first organic emitting layer 2033a that emits red light and the second organic emitting layer 2033b that emits green light require substantially a same drive voltage, so that the first organic emitting layer 2033a and the second organic emitting layer 2033b can be provided adjacently, that is, the first organic emitting layer 2033a and the second organic emitting layer 2033b may be sequentially provided between the hole transport layer 2032a and the electron transport layer 2034a.

In an exemplary implementation, the second light emitting functional layer 203b may include a hole injection layer 2031b, a hole transport layer 2032b, a third organic emitting layer 2033c, an electron transport layer 2034b, and an electron injection layer 2034b provided sequentially along a direction away from the base substrate 101. The third organic emitting layer 2033c may emit blue light. Since a drive voltage of the third organic emitting layer 2033c that emits blue light is different from drive voltages of the first organic emitting layer 2033a and the second organic emitting layer 2033b described above, the third organic emitting layer 2033c is separately provided.

In an exemplary implementation, the charge generation layer 204 can enhance the conductivity of carriers to ensure that both the first light emitting functional layer 203a and the second light emitting functional layer 203b can emit light normally.

The present disclosure further provides a method for manufacturing a display panel, wherein the display panel includes a base substrate, the base substrate includes a light emitting region and a non-light emitting region, and the method for manufacturing the display panel includes:
forming a first electrode part on a light emitting region of the base substrate and forming a second electrode part on a non-light emitting region of the base substrate;
wherein the second electrode part is located on at least one side of the first electrode part; the first electrode part is electrically connected with the second electrode part and a square resistance of the first electrode part is greater than a square resistance of the second electrode part.

In an exemplary implementation, forming the first electrode part on the light emitting region of the base substrate and forming the second electrode part on the non-light emitting region of the base substrate includes:
forming a conductive material layer on the base substrate, wherein the conductive material layer covers the light emitting region and the non-light emitting region;
forming a first dielectric layer on the conductive material layer on the non-light emitting region;
etching the conductive material layer on the light emitting region so that a thickness of the conductive material layer on the light emitting region is less than a thickness of the conductive material layer on the non-light emitting region; forming the first electrode part by the conductive material layer on the light emitting region and forming the second electrode part by the conductive material layer on the non-light emitting region.

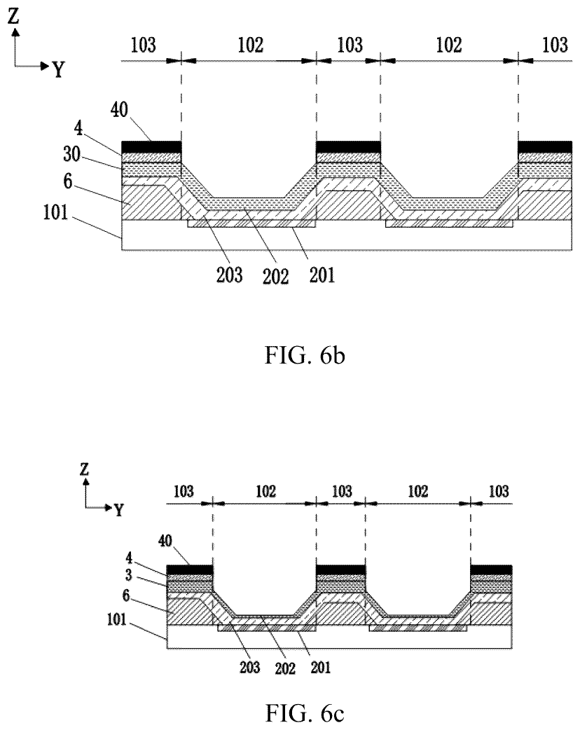

An exemplary description will be given for a structure and a manufacturing process of a display panel below with reference to FIG. 6a to FIG. 6d.

A “patterning process” mentioned in the embodiments of the present disclosure includes treatments such as photoresist coating, mask exposure, development, etching, and photoresist stripping for a metal material, an inorganic material, or a transparent conductive material, and includes treatments such as organic material coating, mask exposure, and development for an organic material. The deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

In an exemplary embodiment, the manufacturing process of the display panel may include the following.

### (1) A Base Substrate is Provided.

In an exemplary embodiment, the base substrate includes: a light emitting region and a non-light emitting region and the non-light emitting region is located at an outer side of the light emitting region. The base substrate may be a rigid base substrate or a flexible base substrate. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers.

In an exemplary embodiment, the flexible base substrate may include a first flexible material layer, a first inorganic material layer, a second flexible material layer and a second inorganic material layer which are stacked. Materials of the first and second flexible material layers may be polyimide (PI), polyethylene terephthalate (PET), surface treated polymer soft films, or the like, and materials of the first and second inorganic material layers may be silicon nitride (SiNₓ), silicon oxide (SiOₓ), or the like, for improving water and oxygen resistance of the base substrate.

### (2) A Conductive Material Layer is Formed.

In an exemplary embodiment, formation of the conductive material layer includes: firstly, a second electrode 201, a pixel definition layer 6 and a light emitting functional layer 203 are sequentially formed on the base substrate 101. Among them, the second electrode 201 is located on the light emitting region 102 of the base substrate 101 and the second electrode 201 can be used as an anode of a light emitting unit. At least part of the pixel definition layer 6 is located on the non-light emitting region 103 of the base substrate 101, an opening is provided in the pixel definition layer 6, the opening is located on the light emitting region 102 of the base substrate 101, and the opening exposes at least part of the second electrode 201. The light emitting functional layer 203 is located on the light emitting region 102 and the non-light emitting region 103 of the base substrate 101, a part of the light emitting functional layer 203 is provided on a side of the pixel definition layer 6 away from the base substrate 101, a part of the light emitting functional layer 203 covers an inner wall of the opening and the exposed second electrode 201, and a part of the light emitting functional layer 203 is electrically connected with the exposed second electrode 201.

Then, a conductive thin film is deposited on the base substrate 101 on which the aforementioned structures are formed, and the conductive thin film is patterned through a patterning process so that the conductive thin film is formed into the conductive material layer 30 provided on the light emitting functional layer 203, as shown in FIG. 6a. Among them, the conductive material layer 30 is located on the light emitting region 102 and the non-light emitting region 103 of the base substrate 101.

### (3) A First Dielectric Layer is Formed.

In an exemplary embodiment, formation of the first dielectric layer includes: a first dielectric thin film covering the conductive material layer 30 is deposited on the base substrate 101 on which the aforementioned patterns are formed.

Then, a photoresist thin film is coated on the first dielectric thin film, the photoresist thin film is exposed through a mask plate, so that the photoresist thin film forms an exposed region and an unexposed region, wherein the exposed region is located in the light emitting region 102 and the unexposed region is located in the non-light emitting region 103.

Next, the photoresist thin film in the exposed region is removed by a development process to expose the first dielectric film in the light emitting region 102, and the photoresist thin film 40 in the unexposed area is retained.

Finally, the first dielectric thin film in the light emitting region 102 is etched and removed by an etching process to expose the conductive material layer 30 in the light emitting region 102. The first dielectric thin film located in the non-light emitting region 103 is formed into a first dielectric layer 4, as shown in FIG. 6b. Among them, the first dielectric layer 4 is located on the non-light emitting region 103 of the base substrate 101, the conductive material layer 30 located on the non-light emitting region 103 is covered by the first dielectric layer 4, and the conductive material layer 30 located on the light emitting region 102 is not covered by the first dielectric layer 4, as shown in FIG. 6b.

### (4) A First Electrode Part and a Second Electrode Part are Formed.

In an exemplary embodiment, formation of the first electrode part and the second electrode part includes: on the base substrate 101 on which the aforementioned patterns are formed, a part of the conductive material layer 30 on the light emitting region 102 is removed by etching, so that the conductive material layer 30 on the light emitting region 102 forms the first electrode part 202; since the conductive material layer 30 on the non-light emitting region 103 is covered by the first dielectric layer 4 and the photoresist thin film 40, the conductive material layer 30 on the non-light emitting region 103 is not etched to form the second electrode part 3, as shown in FIG. 6c. Among them, a thickness of the first electrode part 202 is less than a thickness of the second electrode part 3.

### (5) A Second Dielectric Layer is Formed.

In an exemplary embodiment, formation of the second dielectric layer includes: on the base substrate 101 on which the aforementioned patterns are formed, the first dielectric layer 4 by is exposed removing the photoresist thin film on the non-light emitting region 103 through an ashing process; then, a second dielectric thin film is deposited on the first electrode part 202 and the first dielectric layer 4, and the second dielectric thin film is patterned through a patterning process so that the second dielectric thin film forms the second dielectric layer 5 covering the first electrode part 202 and the first dielectric layer 4, as shown in FIG. 2.

The manufacturing process in the present disclosure may be compatible well with an existing manufacturing process, is simple in process implementation, is easy to implement, and has a high production efficiency, a low production cost, and a high yield.

The present disclosure further provides a display device, including the display panel of the aforementioned exemplary embodiment. The display device may be any product or component with a display function, such as a mobile phone, a tablet computer, a television, a display, a laptop computer, a digital photo frame, or a navigator.

Although the implementations disclosed in the present disclosure are described as above, the described contents are only implementations which are used for facilitating the understanding of the present disclosure, but are not intended to limit the present disclosure. Any one skilled in the art to which the present disclosure pertains may make any modifications and variations in forms and details of implementations without departing from the spirit and scope of the present disclosure. However, the patent protection scope of the present disclosure should be subject to the scope defined by the appended claims.

1. A display panel, comprising:
a base substrate, comprising a light emitting region and a non-light emitting region;
at least one light emitting unit located on the light emitting region, wherein each light emitting unit comprises a first electrode part;
a second electrode part located on the non-light emitting region, wherein the second electrode part is located on at least one side of the first electrode part and electrically connected with the first electrode part; and
a square resistance of the first electrode part is greater than a square resistance of the second electrode part.

2. The display panel according to claim 1, wherein a thickness of the first electrode part is less than a thickness of the second electrode part.

3. The display panel according to claim 2, wherein a ratio of the thickness of the first electrode part to the thickness of the second electrode part is 1/5 to 1/10.

4. The display panel according to claim 3, wherein the first electrode part has a thickness value of 100 angstroms to 200 angstroms and the second electrode part has a thickness value of 500 angstroms to 1000 angstroms.

5. The display panel according to claim 1, wherein a plurality of light emitting units are arranged along a first direction of the base substrate to form a light emitting unit row, and second electrode parts are located on one side or two sides in a second direction of all or part of the light emitting units in the light emitting unit row, and the first direction intersects with the second direction.

6. The display panel according to claim 5, wherein a part of the light emitting units in the light emitting unit row forms a first pixel island, and a part of the light emitting units in the light emitting unit row forms a second pixel island, the first pixel island and the second pixel island are disposed adjacent to each other, the first pixel island is configured to display a first picture, the second pixel island is configured to display a second picture, and the first picture and the second picture are spliced to form a continuous image.

7. The display panel according to claim 6, wherein the light emitting units in the first pixel island form a first sub-picture, and the light emitting units in the second pixel island form a second sub-picture, and the first sub-picture and the second sub-picture are alternately arranged to form the continuous image.

8. The display panel according to claim 5, wherein the second electrode parts are in a strip shape and the second electrode parts extend along the first direction.

9. The display panel according to claim 5, wherein all or part of the light emitting units in the light emitting unit row emit light of a same color.

10. The display panel according to claim 5, wherein the plurality of light emitting units are arranged along the second direction of the base substrate to form a light emitting unit column and at least part of the second electrode parts are located between all or part of adjacent light emitting units in the light emitting unit column.

11. The display panel according to claim 10, wherein all or part of the light emitting units in the light emitting unit column emit light of different colors.

12. The display panel according to claim 5, further comprising third electrode parts, the third electrode parts are located on the non-light emitting region, the third electrode parts are located on one side or two sides in the first direction of all or part of the light emitting units in the light emitting unit row, the third electrode parts are electrically connected with first electrode parts, and a square resistance of a third electrode part is greater than a square resistance of a second electrode part.

13. The display panel according to claim 12, wherein a thickness of the third electrode part is less than a thickness of the second electrode part.

14. The display panel according to claim 1, wherein the first electrode part and the second electrode part are integrally formed.

15. The display panel according to claim 1, further comprising a first dielectric layer, wherein the first dielectric layer is located on the non-light emitting region, the first dielectric layer is provided on a side of the second electrode part away from the base substrate, and an orthographic projection of the first dielectric layer on the base substrate is not overlapped with an orthographic projection of the first electrode part on the base substrate.

16. The display panel according to claim 15, further comprising a second dielectric layer, wherein the second dielectric layer is located on the light emitting region and the non-light emitting region, the second dielectric layer is provided on a side of the first dielectric layer away from the base substrate, and the second dielectric layer covers at least a part of the first electrode part and at least a part of the first dielectric layer.

17. The display panel according to claim 1, further comprising a pixel definition layer, at least part of the pixel definition layer is located on the non-light emitting region, and at least part of the second electrode part is provided on a side of the pixel definition layer away from the base substrate; or
wherein each light emitting unit further comprises a second electrode and a light emitting layer, the second electrode and the light emitting layer are located on the light emitting region, the second electrode is located on a side of the first electrode part close to the base substrate, and the light emitting layer is located between the second electrode and the first electrode part; or
the display panel further comprises a lens layer, the lens layer is located on a side of the light emitting unit away from the base substrate, and an orthographic projection of the lens layer on the base substrate is overlapped with an orthographic projection of the light emitting unit on the base substrate.

18-19. (canceled)

20. A display device, comprising the display panel according to claim 1.

21. A method for manufacturing a display panel, wherein the display panel comprises a base substrate, the base substrate comprises a light emitting region and a non-light emitting region, and the method comprises:
forming a first electrode part on the light emitting region of the base substrate and forming a second electrode part on the non-light emitting region of the base substrate;
wherein the second electrode part is located on at least one side of the first electrode part; the first electrode part is electrically connected with the second electrode part, and a square resistance of the first electrode part is greater than a square resistance of the second electrode part.

22. The method for manufacturing the display panel according to claim 21, wherein forming the first electrode part on the light emitting region of the base substrate and forming the second electrode part on the non-light emitting region of the base substrate comprises:
forming a conductive material layer on the base substrate, wherein the conductive material layer covers the light emitting region and the non-light emitting region;
forming a first dielectric layer on the conductive material layer on the non-light emitting region; and
etching the conductive material layer on the light emitting region so that a thickness of the conductive material layer on the light emitting region is less than a thickness of the conductive material layer on the non-light emitting region; forming the first electrode part by the conductive material layer located on the light emitting region and forming the second electrode part by the conductive material layer located on the non-light emitting region.
